(19) United States
(12) Patent Application Publication
(10) Pub. No.: US 2026/0006776 A1
(43) Pub. Date: Jan. 1, 2026

(54) SEMICONDUCTOR DEVICE HAVING VERTICAL CHANNEL TRANSISTOR AND METHOD FOR MANUFACTURING THE SAME

(71) Applicant: NANYA TECHNOLOGY CORPORATION, NEW TAIPEI CITY (TW)

(72) Inventor: TSENG-FU LU, NEW TAIPEI CITY (TW)

(21) Appl. No.: 18/804,416

(22) Filed: Aug. 14, 2024

Related U.S. Application Data
(62) Division of application No. 18/760,207, filed on Jul. 1, 2024.

(51) Int. Cl. H10B 12/00; H01L 29/10

(52) U.S. Cl. CPC H10B 12/488; H10B 12/482; H10B 12/485; H10D 62/314

(57) ABSTRACT

A semiconductor device and a method of manufacturing a semiconductor device are provided. The semiconductor device includes a bit line extending in a first direction, a first word line extending in a second direction and disposed over the bit line, and a second word line extending in the second direction and disposed over the bit line. The semiconductor device also includes a first pillar structure overlapping the first word line and the second word line.

### CROSS-REFERENCE TO RELATED APPLICATION

This application is a divisional application of U.S. Non-Provisional application Ser. No. 18/760,207 filed Jul. 1, 2024, which is incorporated herein by reference in its entirety.

### TECHNICAL FIELD

The present disclosure relates to a semiconductor device and a method for manufacturing a semiconductor device, and more particularly, to a semiconductor device having a vertical channel transistor.

### DISCUSSION OF THE BACKGROUND

Dynamic random access memory (DRAM) is a crucial component in modern computing, and it includes a plurality of memory cells. Each memory cell comprises a cell transistor and a cell capacitor that work together to store and retrieve data. DRAM operates by manipulating word lines and bit lines to control the cell transistors, facilitating the reading and writing of data to the memory cells.

In order to enhance the efficiency and capacity of DRAM, the size of the unit memory cell has been significantly reduced. This reduction in size, from a six square feature size (6F²) to a four square feature size (4F²), has allowed for a decrease in the footprint of the DRAM cells and a subsequent increase in the integration density of multiple DRAM cells within the memory array.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a bit line extending in a first direction, a first word line extending in a second direction and disposed over the bit line, and a second word line extending in the second direction and disposed over the bit line. The semiconductor device also includes a first pillar structure overlapping the first word line and the second word line.

Another aspect of the present disclosure provides a semiconductor device. The semiconductor device includes a bit line, and a first pillar structure disposed over the bit line having a first surface and a second surface. The semiconductor device also includes a first word line connecting to the first surface of the first pillar structure, and a second word line connecting to the second surface of the first pillar structure.

Another aspect of the present disclosure provides a method of manufacturing a semiconductor device. The method includes forming a bit line extending in a first direction, forming a first word line extending in a second direction and disposed over the bit line, and forming a second word line extending in the second direction and disposed over the bit line. The method also includes forming a pillar structure overlapping the first word line and the second word line.

By overlapping a vertical channel transistor with two word lines, the spacing between the word lines can be reduced without compromising their width. This innovative design also allows for the selection of one memory cell by two word lines, effectively preventing interference between word lines in different memory cells. As a result, the data retention time is prolonged, and the overall operational reliability of the semiconductor device is significantly enhanced.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

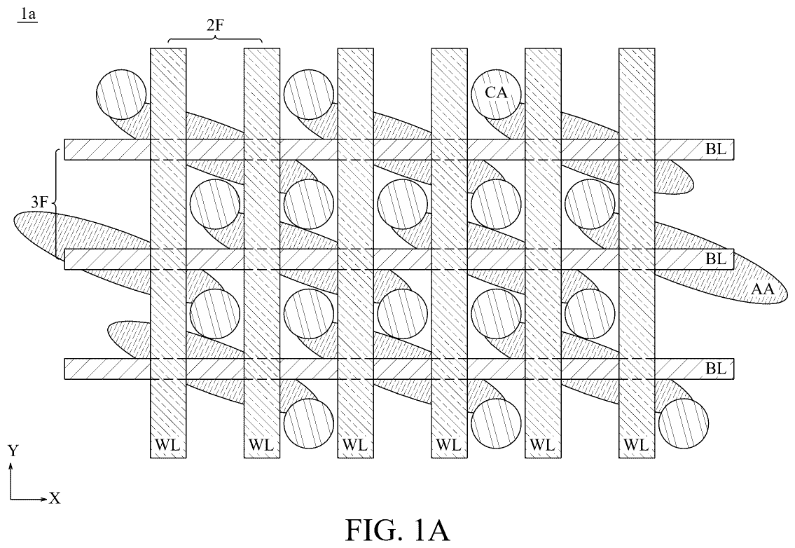

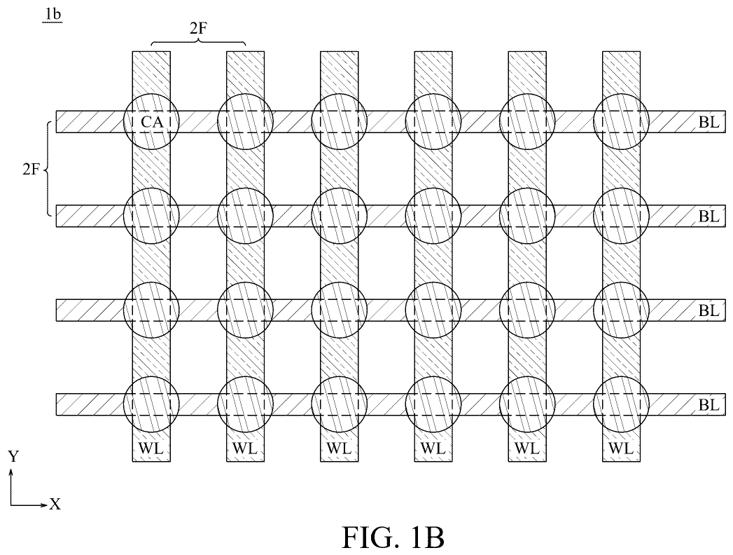

FIG. 1A is a schematic top plan view of a portion of a semiconductor device, in accordance with some embodiments of the present disclosure.

FIG. 1B is a schematic top plan view of a portion of a semiconductor device, in accordance with some embodiments of the present disclosure.

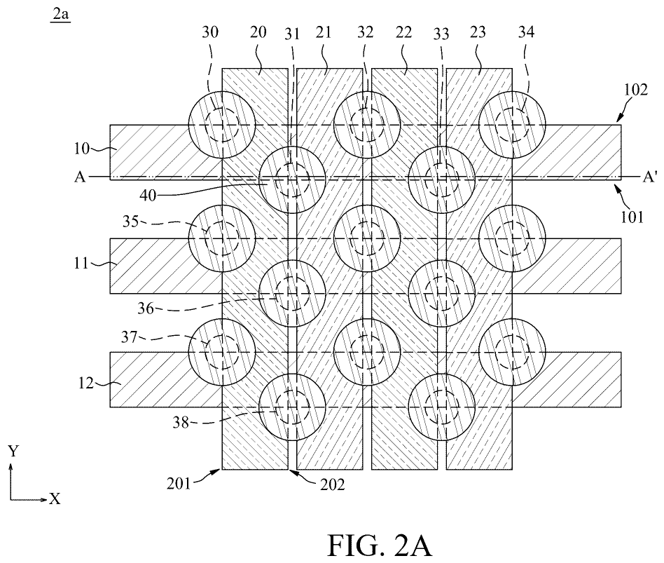

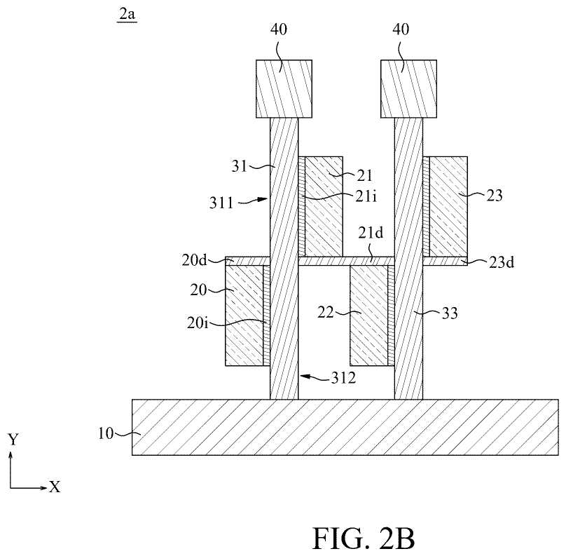

FIG. 2A is a schematic top plan view of a portion of a semiconductor device, in accordance with some embodiments of the present disclosure.

FIG. 2B is a schematic cross-sectional view of a semiconductor device in accordance with some embodiments of the present disclosure.

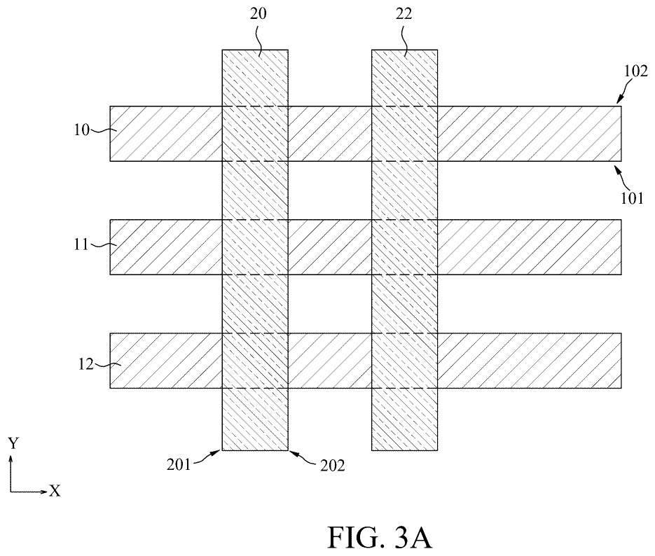

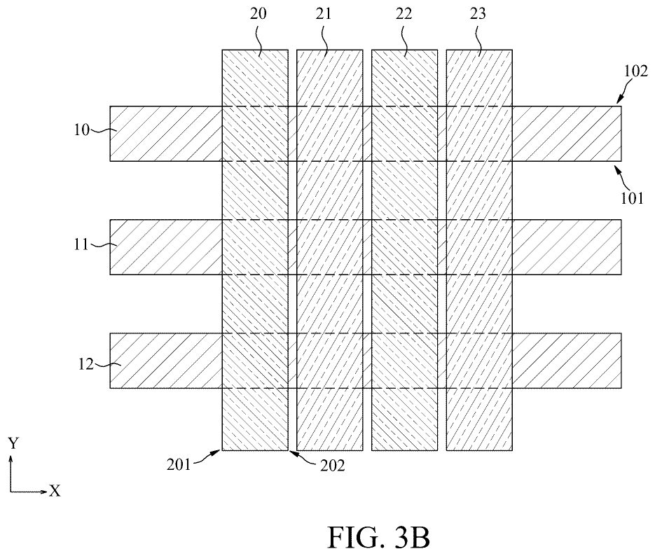

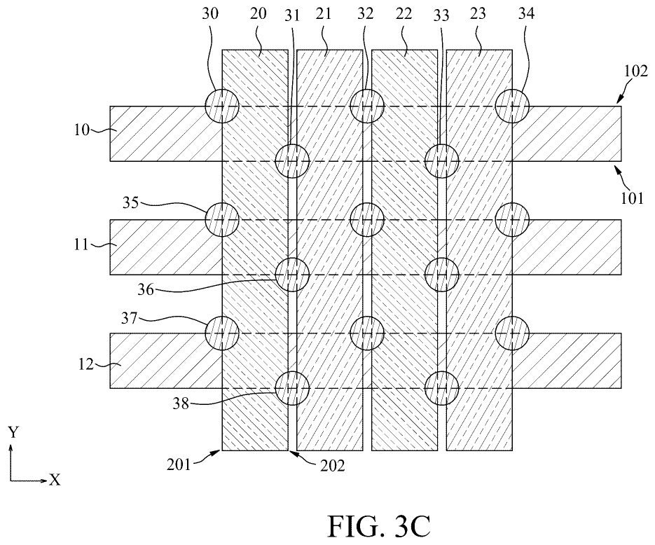

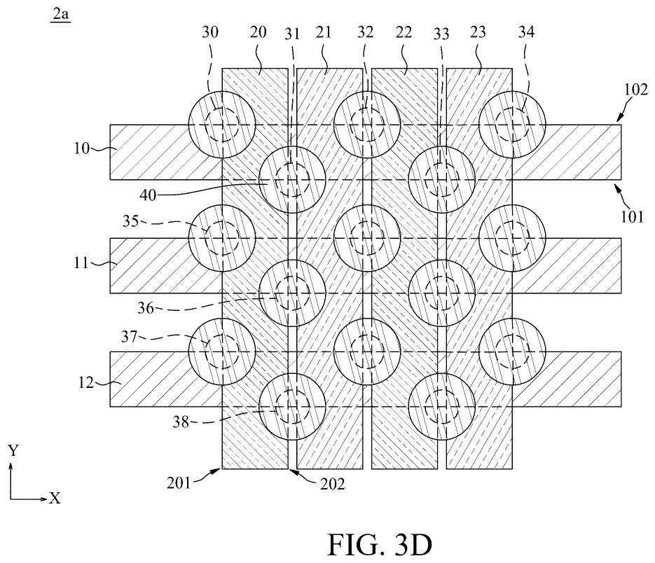

FIG. 3A is a schematic top plan view illustrating one or more stages of a method of manufacturing a semiconductor device in accordance with some embodiments of the present disclosure.

FIG. 3B is a schematic top plan view illustrating one or more stages of a method of manufacturing a semiconductor device in accordance with some embodiments of the present disclosure.

FIG. 3C is a schematic top plan view illustrating one or more stages of a method of manufacturing a semiconductor device in accordance with some embodiments of the present disclosure. FIG. 3D is a schematic top plan view illustrating one or more stages of a method of manufacturing a semiconductor device in accordance with some embodiments of the present disclosure.

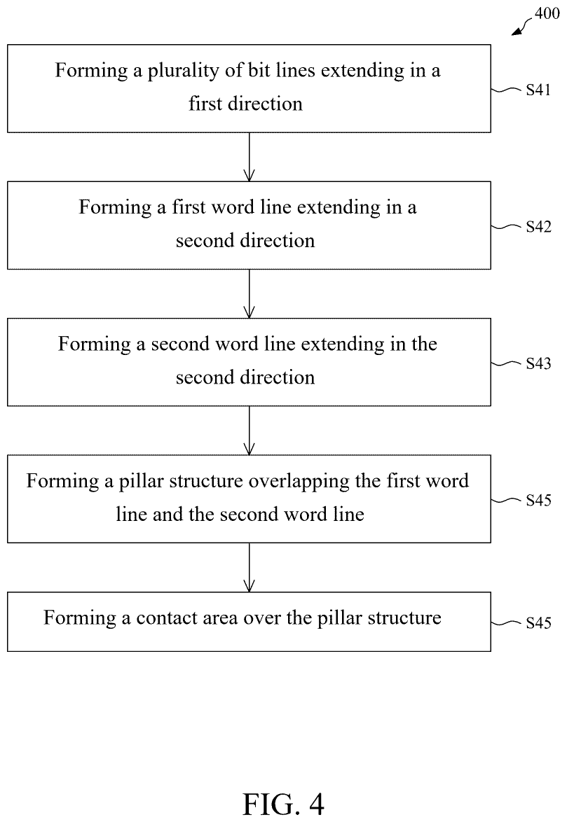

FIG. 4 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1A is a schematic top plan view of a portion of a semiconductor device 1a, in accordance with some embodiments of the present disclosure.

In some embodiments, the semiconductor device 1a may be disposed adjacent to a circuit. For example, the semiconductor device 1a may be disposed adjacent to a memory device such as a dynamic random access memory (DRAM) device or the like.

Referring to FIG. 1A, the semiconductor device 1a may include a plurality of bit lines BL extending in a first direction X and a plurality of word lines WL extending in a second direction Y crossing the bit lines BL. The second direction Y may be distinct from the first direction X. The second direction Y may be substantially perpendicular to the first direction X. The bit lines BL and the word lines WL may each be striated or have a stripe structure. The bit lines BL and the word lines WL form or define a plurality of grids.

The semiconductor device 1a may include a plurality of active regions AA defined by isolation regions (not shown in the figures), such as shallow trench isolation (STI) structures. The active regions AA may be diagonally disposed with respect to the extending direction of the bit lines BL or the extending direction of the word lines WL (e.g., the first direction X or the second direction Y).

The semiconductor device 1a may include a plurality of contact areas CA. The contact areas CA may each be formed in a grid defined by the bit lines BL and the word lines WL. The contact areas CA may be electrically connected with a memory element. In some embodiments, the memory element may be a capacitor. In other embodiments, the memory element may be a variable resistance pattern capable of switching between two resistance states by an electrical pulse applied to the memory element. For example, the memory element may include a phase change material capable of changing a crystalline state according to an amount of electrical current, such as perovskite compounds, transition metal oxide, magnetic materials, ferromagnetic materials or antiferromagnetic materials.

In some embodiments, the bit lines BL and the word lines WL may each have a width of 1F (where F is the minimum lithographic feature size). The bit lines BL may be spaced apart from one another by 1F. The word lines WL may be spaced apart from one another by 1F. Therefore, the area of a unit memory cell in FIG. 1A is about 2F×3F=6F².

FIG. 1B is a schematic top plan view of a portion of a semiconductor device 1b, in accordance with some embodiments of the present disclosure.

The contact areas CA of the semiconductor device 1b may be disposed at the intersection of the bit lines BL and the word lines WL. Therefore, the area of the unit memory cell in FIG. 1B is about 2F×2F=4F².

The evolution of memory array layout has led to a reduction in the size of a unit memory cell, with the transition from a six square feature size (6F²) to a four square feature size (4F²). This reduction is primarily attributed to the decrease in the minimum feature size F and the coefficient α, which decreases with each new generation. The key distinction between the 6F² and 4F² layouts lies in the implementation of the cell structure. The 4F² layout utilizes a vertical pillar transistor, while the 6F² layout employs a buried-channel-array transistor. The 4F² architecture, with the vertical pillar transistor, is a promising approach for achieving cost-effective and scalable DRAM chips.

FIG. 2A is a schematic top plan view of a portion of a semiconductor device 2a, in accordance with some embodiments of the present disclosure.

The semiconductor device 2a may include a plurality of bit lines 10, 11, 12 extending in the first direction X. The semiconductor device 2a may include a plurality of word lines 20, 21, 22, 23 extending in the second direction Y crossing the bit lines 10, 11, and 12.

The bit lines 10, 11, 12 may be disposed over the substrate (not shown in the figures). In some embodiments, the bit lines 10, 11, 12 may be disposed in the substrate.

The substrate may include a semiconductor substrate. In some embodiments, the semiconductor material of the substrate may include, for example, silicon (Si) (such as monocrystalline silicon, polysilicon, and amorphous silicon), germanium (Ge), gallium (Ga), and indium (In). In some embodiments, the semiconductor material of the substrate may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate may be a wafer, such as a silicon wafer. The substrate may be doped (e.g., with a P-type or an N-type dopant) or undoped.

The word lines 20, 21, 22, and 23 may include any suitable material, such as tungsten (W), ruthenium (Ru), cobalt (Co), titanium (Ti), tantalum (Ta), copper (Cu), aluminum (Al), gold (Au), titanium nitride (TiN), tantalum nitride (TaN), tungsten nitride (W₂N, WN, WN₂), the like, or combinations thereof.

The semiconductor device 2a may include a plurality of pillar structures 30, 31, 32, 33, 34, 35, 36, 37, and 38. The pillar structures 30, 31, 32, 33, 34, 35, 36, 37, and 38 may each be or include a channel region of a vertical channel transistor. The pillar structures 30, 31, 32, 33, 34, 35, 36, 37, and 38 may be disposed over the bit lines 10, 11, and 12.

The pillar structures 30, 31, 32, 33, 34, 35, 36, 37, and 38 may include any suitable material, such as indium gallium zinc oxide (IGZO), indium aluminum zinc oxide (IAZO), polysilicon, the like, or combinations thereof.

The pillar structures 30, 31, 32, 33, and 34 may be arranged along the bit line 10. The pillar structures 30, 31, 32, 33, and 34 may be alternately arranged on opposite sides of the bit line 10 along the first direction X. For example, the bit line 10 may include a surface 101 and a surface 102 opposite to the surface 101. The pillar structures 30, 31, 32, 33, and 34 may be alternately overlapped with the surface 101 and the surface 102 of the bit line 10 along the first direction X.

The pillar structures 30, 31, 35, 36, 37, and 38 may be arranged along the word line 20. The pillar structures 30, 31, 35, 36, 37, and 38 may be alternately arranged on opposite sides of the word line 20 along the second direction Y. For example, the word line 20 may include a surface 201 and a surface 202 opposite to the surface 101. The pillar structures 30, 31, 35, 36, 37, and 38 may be alternately overlapped with the surface 201 and the surface 202 of the word line 20 along the second direction Y.

Some of the pillar structures may be overlapped with two adjacent ones of the word lines 20, 21, 22, and 23. For example, the pillar structures 31, 36, and 38 may each be overlapped with the word lines 20 and 21. For example, the pillar structures 31, 36, and 38 may each be disposed between the word lines 20 and 21. For example, the pillar structure 32 may each be overlapped with the word lines 21 and 22. For example, the pillar structure 33 may each be overlapped with the word lines 22 and 23.

The semiconductor device 2a may include a plurality of contact areas 40 disposed over the pillar structures. The contact areas 40 may each include a conductive material. The contact areas 40 may each include a doped semiconductor material (e.g., doped silicon), a metal (e.g., tungsten, titanium, and tantalum), a conductive metal nitride (e.g., titanium nitride, tantalum nitride, and tungsten nitride), and a metal-semiconductor compound (e.g., a metal silicide). The contact areas 40 may be vertically overlapped with the pillar structures. The contact areas 40 may be electrically connected with the pillar structures.

FIG. 2B illustrates a cross-sectional view of the semiconductor device 2a taken along lines A-A′ of FIG. 2A.

The pillar structures 31 and 33 may be disposed over the bit line 10. The pillar structures 31 and 33 may be spaced apart from each other. The pillar structures 31 and 33 may each be electrically connected with the contact area 40.

The pillar structures 31 and 33 may extend in a third direction Z. The third direction Z may be distinct from the first direction X. The third direction Z may be substantially perpendicular to the first direction X.

The pillar structure 31 may be connected with the word lines 20 and 21. The word lines 20 and 21 may be separated from each other by the pillar structure 31. For example, the pillar structure 31 may include a surface 311 and a surface 312 opposite to the surface 101. The surface 311 and the surface 312 may be substantially perpendicular to the bit line 10.

The word line 20 may be disposed over (or connected with) the surface 311 of the pillar structure 31 through a gate dielectric 20i. The word line 21 may be disposed over (or connected with) the surface 312 of the pillar structure 31 through a gate dielectric 21i. The gate dielectrics 20i and 21i may include, for example, silicon oxide (SiO₂), silicon nitride (Si₃N₄) and/or silicon oxynitride. In some embodiments, the gate dielectrics 20i and 21i may be formed by any suitable process, such as low-pressure chemical vapor deposition (LPCVD), plasma enhanced-chemical vapor deposition (PECVD), atomic layer deposition (ALD), or physical vapor deposition (PVD), thermal growth, or chemical growth.

The word lines 20 and 21 may not be overlapped with each other along the first direction X. For example, the word lines 20 and 21 may be disposed at different elevations with respect to the bit line 10.

For example, the word line 20 may be disposed over a lower portion of the pillar structure 31. For example, the word line 20 may be disposed closer to the bit line 10 than the word line 21 is. For example, the word line 21 may be disposed over an upper portion of the pillar structure 31. For example, the word line 21 may be disposed closer to the contact area 40 than the word line 20 is.

The word lines and bit lines of the semiconductor device 2a may control the operation of the semiconductor device 2a. For example, at the beginning of a read or write operation, a voltage corresponding to a high data value may be applied to the bit line 10, which may correspond to multiple memory cells (which include the pillar structures 30, 31, 32, 33, and 34). Then, one memory cell may be selected by two adjacent word lines 20, 21, 22, and 23. For example, one memory cell may be selected by turning on the pillar structure 31 through the word lines 20 and 21. Therefore, the word lines 20 and 21 may be configured to turn on the pillar structure 31. The memory cell including the pillar structure 31 may be selected by the bit line 10 and the word lines 20 and 21.

Similarly, the pillar structure 33 may be connected with the word lines 22 and 23. The word lines 22 and 23 may be configured to turn on the pillar structure 33. The memory cell including the pillar structure 33 may be selected by the bit line 10 and the word lines 22 and 23. Dielectric layers 20d, 21d, and 23d may be disposed over the word lines 20, 21, 22, and 23. The dielectric layer 20d may be disposed over the word line 20 and may configured to isolate the word line 20 from the other word lines. The dielectric layers 20d, 21d, and 23d may include an oxide layer.

As DRAM devices become more integrated, shrinking the word line and bit line is necessary to expand the process window and mitigate risks such as current shortages and capacitive coupling. However, this shrinkage can lead to increased resistance in the word line and bit line, which poses a challenge in achieving high-speed performance in semiconductor devices.

By overlapping a vertical channel transistor with two word lines, the spacing between the word lines can be reduced without compromising their width. This innovative design also allows for the selection of one memory cell by two word lines, effectively preventing interference between word lines in different memory cells. As a result, the data retention time is prolonged, and the overall operational reliability of the semiconductor device is significantly enhanced.

FIGS. 3A, 3B, 3C, and 3D illustrate stages of a method of manufacturing a semiconductor device in accordance with some embodiments of the present disclosure. At least some of these figures have been simplified for a better understanding of the aspects of the present disclosure. In some embodiments, the semiconductor device 2a in FIG. 2A may be manufactured by the operations described below with respect to FIGS. 3A, 3B, 3C, and 3D.

As shown in FIG. 3A, the method may include forming a plurality of bit lines 10, 11, and 12 extending in the first direction X and a plurality of word lines 20 and 22 extending in the second direction Y crossing the bit lines 10, 11, and 12. The word lines and the bit lines may form or define a plurality of grids. The word lines and the bit lines may be formed by any suitable process, such as chemical vapor deposition (CVD), physical vapor deposition (PVD), or damascene process. In some embodiments, dielectric layers (such as the dielectric layers 20d, 21d, and 23d in FIG. 2B) may be disposed over the word lines 20 and 22.

As shown in FIG. 3B, the method may include forming a plurality of word lines 21 and 23 extending in the second direction Y crossing the bit lines 10, 11, and 12. In some embodiments, the word lines 20, 21, 22, and 23 may be formed in the same operation. In some embodiments, the word lines 20, 21, 22, and 23 may be formed in different operations.

As shown in FIG. 3C, the method may include forming a plurality of pillar structures 30, 31, 32, 33, 34, 35, 36, 37, and 38. In some embodiments, the pillar structures 30, 31, 32, 33, 34, 35, 36, 37, and 38 may be formed by any suitable process. For example, the dielectric layer among the word lines 20, 21, 22, and 23 may be removed by any suitable etching operation, such as a wet etching operation. Then, the material of the pillar structure may be disposed in the space among the word lines 20, 21, 22, and 23.

In some embodiments, the pillar structures 30, 31, 32, 33, 34, 35, 36, 37, and 38 may be formed before the operation of forming the word lines 20, 21, 22, and 23. For example, the pillar structures may be formed by performing an etching operation on a silicon-based layer. For example, the pillar structures may be formed by epitaxial growth.

As shown in FIG. 3D, the method may include forming a plurality of contact areas 40 over the pillar structures 30, 31, 32, 33, 34, 35, 36, 37, and 38. The contact areas 40 may be formed by any suitable process, such as chemical vapor deposition (CVD), physical vapor deposition (PVD), or damascene process.

FIG. 4 illustrates a flow chart of a method 400 of manufacturing a semiconductor device in accordance with some embodiments of the present disclosure.

In some embodiments, the method 400 may include a step S41 of forming a plurality of bit lines extending in a first direction. For example, as shown in FIG. 3A, the method may include forming a plurality of bit lines 10, 11, and 12 extending in the first direction X.

In some embodiments, the method 400 may include a step S42 of forming a first word line extending in a second direction. For example, as shown in FIG. 3A, the method may include forming a plurality of word lines 20 and 22 extending in the second direction Y crossing the bit lines 10, 11, and 12.

In some embodiments, the method 400 may include a step S43 of forming a second word lines extending in the second direction. For example, as shown in FIG. 3B, the method may include forming a plurality of word lines 21 and 23 extending in the second direction Y crossing the bit lines 10, 11, and 12.

In some embodiments, the method 400 may include a step S44 of forming a pillar structure overlapping the first word line and the second word line. For example, as shown in FIG. 3C, the method may include forming a plurality of pillar structures 30, 31, 32, 33, 34, 35, 36, 37, and 38.

In some embodiments, the method 400 may include a step S45 of forming a contact area over the pillar structure. For example, as shown in FIG. 3D, the method may include forming a plurality of contact areas 40 over the pillar structures 30, 31, 32, 33, 34, 35, 36, 37, and 38.

One aspect of the present disclosure provides a semiconductor device. The semiconductor device includes a bit line extending in a first direction, a first word line extending in a second direction and disposed over the bit line, and a second word line extending in the second direction and disposed over the bit line. The semiconductor device also includes a first pillar structure overlapping the first word line and the second word line.

Another aspect of the present disclosure provides a semiconductor device. The semiconductor device includes a bit line, and a first pillar structure disposed over the bit line having a first surface and a second surface. The semiconductor device also includes a first word line connecting to the first surface of the first pillar structure, and a second word line connecting to the second surface of the first pillar structure.

Another aspect of the present disclosure provides a method of manufacturing a semiconductor device. The method includes forming a bit line extending in a first direction, forming a first word line extending in a second direction and disposed over the bit line, and forming a second word line extending in the second direction and disposed over the bit line. The method also includes forming a pillar structure overlapping the first word line and the second word line.

By overlapping a vertical channel transistor with two word lines, the spacing between the word lines can be reduced without compromising their width. This innovative design also allows for the selection of one memory cell by two word lines, effectively preventing interference between word lines in different memory cells. As a result, the data retention time is prolonged, and the overall operational reliability of the semiconductor device is significantly enhanced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a bit line;
a first pillar structure disposed over the bit line, wherein the first pillar structure has a first surface and a second surface opposite to the first surface;
a first word line connecting to the first surface of the first pillar structure; and
a second word line connecting to the second surface of the first pillar structure.

2. The semiconductor device of claim 1, wherein the first surface and the second surface of the first pillar structure are substantially perpendicular to the bit line.

3. The semiconductor device of claim 1, wherein the first word line is connected to the first surface of the first pillar structure through a gate dielectric.

4. The semiconductor device of claim 1, wherein the first pillar structure includes a channel region of a vertical channel transistor.

5. The semiconductor device of claim 4, wherein the first word line and the second word line are configured to turn on the channel region of the vertical channel transistor.

6. The semiconductor device of claim 5, wherein the bit line, and the first word line and the second word line are configured to select a memory cell including the vertical channel transistor.

7. The semiconductor device of claim 1, wherein the first word line and the second word line are disposed at different elevations with respect to the bit line.

8. The semiconductor device of claim 1, further comprising:
a contact area disposed over the first pillar structure.

9. The semiconductor device of claim 8, wherein the first word line is disposed closer to the contact area than the second word line is.

10. The semiconductor device of claim 1, wherein the bit line extends in a first direction, the first word line extends in a second direction, and the first pillar structure extending in a third direction.

11. The semiconductor device of claim 1, further comprising:
a second pillar structure connecting the first word line and the bit line.

12. The semiconductor device of claim 11, wherein the first pillar structure and the second pillar structure are disposed on opposite sides of the bit line.

13. The semiconductor device of claim 1, further comprising:
a second pillar structure disposed over the bit line;
a third word line connecting to the second pillar structure; and
a fourth word line connecting to the second pillar structure.

14. The semiconductor device of claim 13, wherein the first pillar structure and the second pillar structure are disposed along a side of the bit line.
